(19) United States
(12) Patent Application Publication
(10) Pub. No.: US 2008/0188079 A1
(43) Pub. Date: Aug. 7, 2008

(54) METAL-POLISHING COMPOSITION AND CHEMICAL MECHANICAL POLISHING METHOD BY USING THE SAME

(75) Inventors: Tomoo KATO, Haibara-gun (JP); Takamitsu Tomiga, Haibara-gun (JP); Makoto Kikuchi, Haibara-gun (JP); Sumi Takamiya, Haibara-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/026,849

(22) Filed: Feb. 6, 2008

(30) Foreign Application Priority Data
Feb. 6, 2007 (JP) 2007-027245

(51) Int. Cl. H01L 21/304; C09K 13/00

(52) U.S. Cl. 438/693; 252/79.1; 257/E21.239

(57) ABSTRACT

The present invention provides a metal-polishing composition for use in chemical mechanical polishing of semiconductor devices, comprising:

(a) a compound represented by the following Formula A, (b) a compound represented by the following Formula B, (c) an abrasive grain, and (d) an oxidizing agent:

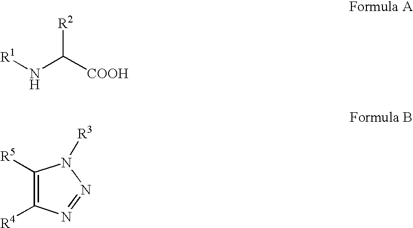

in Formula A, R¹ represents an alkyl group having 1 to 3 carbon atoms; and R² represents a hydrogen atom or an alkyl group having 1 to 4 carbon atoms, and in Formula B, R³, R⁴, and R⁵ each independently represent a hydrogen atom, or an alkyl, aryl, alkoxy, amino, aminoalkyl, hydroxy, hydroxyalkyl, carboxy, carboxyalkyl or carbamoyl group.

### CROSS-REFERENCE TO RELATED APPLICATION

This application claims priority under 35 USC 119 from Japanese Patent Application No. 2007-027245, the disclosure of which is incorporated by reference herein.

### BACKGROUND

1. Technical Field

The present invention relates to a metal-polishing composition and a chemical mechanical polishing method by using the same, and in particular, to a metal-polishing composition for use in flattening semiconductor devices in the wiring formation process of semiconductor device production and a chemical mechanical polishing method by using the same.

2. Related Art

Development of semiconductor devices such as semiconductor integrated circuit (hereinafter, referred to as “LSI”) demands increase in density and further integration by reduction of wiring width and lamination, for miniaturization and increase in operation speed of the devices. For that purpose, various methods including chemical mechanical polishing (hereinafter referred to as “CMP”) have been developed and used. The CMP is a technology essential for surface flattening of processed films such as interlayer insulation film and for formation of plugs, embedded metal wiring, and various substrates are smoothened and redundant thin metal films are removed during wiring formation by using the method (see, for example, U.S. Pat. No. 4,944,836).

Commonly in the CMP method, by placing a polishing pad pasted to a circular polishing surface plate (platen), wetting the polishing pad surface with a polishing solution, pressing the surface of the substrate (wafer) to the pad, rotating both the polishing surface plate and the substrate while a predefined pressure (polishing pressure) is applied from the rear face, and thus, the surface of a substrate is flattened by the mechanical friction generated.

Tungsten and aluminum have conventionally been used as the metal for wiring for an interconnecting structure. However, for further improvement in performance, LSI's using copper having a wiring resistance lower than those of these metals are now under development. Examples of the copper wiring methods include the damascene method described in Japanese Patent Application Laid-Open (JP-A) No. 2-278822. In addition, a dual damascene method of forming contact holes and wiring grooves simultaneously in an interlayer insulation film and embedding a metal therein has been employed increasingly. A high purity copper target having a purity of five nine or more is has been shipped as the target material for such copper wiring.

However, along with recent miniaturization of wiring for further increase in density, there is a demand for improvement of the conductivity and the electronic properties of copper wiring, and thus, use of a copper alloy of high purity copper added another component is now under study. At the same time, there is also a demand for a high-speed metal polishing means of polishing the high-definition high-purity material at high productivity without contamination when polished, the copper metal, which is a soft metal, often shows a phenomenon of giving a dish-shaped dent (dishing) as only the central region is polished deeply, a phenomenon of multiple wiring metal surfaces giving a dish-shaped recess (erosion), and gives a greater number of scratches by polishing (scratching), and thus, there is an increasing need for a high-accuracy polishing technique.

In addition, the diameter of the wafer for production of LSI is expanding consistently recently for improvement in productivity, and currently, wafers having a diameter of 200 mm or more are used commonly, and larger wafers having a diameter of 300 mm or more are also being produced recently. The expansion in diameter of the wafer is accompanied with expansion of the difference in polishing rate between in the wafer central region and in the peripheral region, and there are increasingly stricter requirements imposed on the uniformity of polishing in the wafer surface.

Chemical polishing methods without using mechanical polishing means for copper and copper alloy are known, as described in JP-A No. 49-122432. However, such a chemical polishing method, which utilizes only chemical solubilization, has a serious problem of its surface planarity, because it leads, for example, to dent-shaped abrasion in recess, i.e., dishing, more frequently, compared to the CMP method of polishing raised metal film selectively chemically and mechanically.

When copper wiring is used in production of LSI's, an anti-diffusion layer, called barrier layer, is normally formed between the wiring region and the insulation layer for prevention of diffusion of copper ions into insulating material. The barrier layer is a single-layer or multi-layer of barrier materials selected from TaN, TaSiN, Ta, TiN, Ti, Nb, W, WN, Co, Zr, ZrN, Ru and CuTa alloy. These barrier materials are conductive, and thus, for prevention of troubles for example by leak current, the barrier material on the insulation layer should be removed completely. The removal processing is also performed by a method similar to the bulk polishing of the metal wiring material (barrier CMP).

Because the bulk polishing of copper often results in dishing particularly in the wide metal wiring region, it is desirable to control the polishing amount separately in the wiring region and in the barrier region for desirable final flattening. Accordingly, the polishing solution for barrier polishing desirably has a copper/barrier metal polishing selectivity as high as possible. Because the wiring pitch and the wiring density vary in the wiring layer at each level, it is further desirable to control the polishing selectivity as needed.

The metal polishing composition (metal-polishing solution) for use in CMP generally contains a solid abrasive grain (such as alumina or silica) and an oxidizing agent (such as hydrogen peroxide or persulfuric acid). The basic mechanism of the CMP by using such a metal-polishing solution is considered to be oxidation of metal surface by the oxidizing agent and removal of the resulting oxide film with the abrasive grain, as described, for example, in Journal of Electrochemical Society, 1991, 138, 11, p.3,460 to 3,464.

However, CMP by using such a metal-polishing solution containing a solid abrasive grain may give scratches by polishing (scratching), undesirable polishing on the entire polishing surface (thinning), or dishing and erosion of polishing surface, and the like. The polishing solution remaining on the semiconductor face after polishing is removed normally in the washing process; but use of a polishing solution containing a solid abrasive grain makes the washing process more complicated, and treatment of the washing solution after washing (wastewater) demands sedimentation separation of the solid abrasive grain, which also cause a problem in production cost.

Metal surface polishing methods in combination of a polishing solution containing no abrasive grain and dry etching were disclosed to solve the problems above (see, for example, Journal of Electrochemical Society, 2000, 147, 10, p.3,907 to 3,913), and, for example, a metal-polishing solution containing hydrogen peroxide, malic acid, benzotriazole, ammonium polyacrylate and water was proposed (see for example JP-A No. 2001-127019). It is possible by these methods to perform CMP of the metal film in the raised region of a semiconductor base substance selectively, leaving the metal film in the dents and give a desired conductor pattern. There is less frequent scratching, because the CMP proceeds under friction by a polishing pad mechanically much softer than the conventional slurry containing a solid abrasive grain. However, disadvantageously, decrease in physical polishing force leads to decrease in polishing rate.

On the other hand, an abrasive containing a abrasive grain is characteristic in its high polishing rate, but had a problem of progress of dishing. Accordingly for the purpose of increasing polishing rate while keeping the content of the abrasive grain at the present level, proposed were a method of using a particular organic acid in the polishing solution (see for example JP-A No. 2000-183004) and a method of using an organic acid structure favorable for the polishing solution superior in selectivity between copper and tantalum and resistant to dishing (see for example JP-A No. 2006-179845). However, use of these organic acids, which assured high polishing rate, resulted in increase of copper corrosion rate and easier generation of defects by copper corrosion after polishing, and the resistance to dishing is still practically insufficient, and such polishing solution did not satisfy the requirements in smoothness needed for production of devices.

### SUMMARY

The present inventions have been made in view of the above circumstances and provide a metal-polishing composition and a chemical mechanical polishing method by using the same.

A first aspect of the invention provides a metal-polishing composition for use in chemical mechanical polishing of semiconductor devices, comprising:

(a) a compound represented by the following Formula A, (b) a compound represented by the following Formula B, (c) an abrasive grain, and (d) an oxidizing agent:

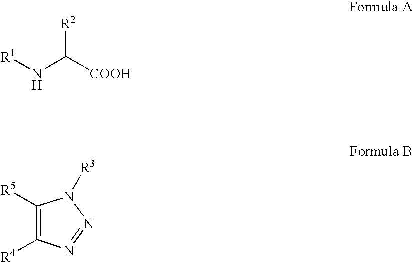

in Formula A, R¹ represents an alkyl group having 1 to 3 carbon atoms; and R² represents a hydrogen atom or an alkyl group having 1 to 4 carbon atoms, and in Formula B, R³, R⁴, and R⁵ each independently represent a hydrogen atom, or an alkyl, aryl, alkoxy, amino, aminoalkyl, hydroxy, hydroxyalkyl, carboxy, carboxyalkyl or carbamoyl group.

A second aspect of the invention provides a chemical mechanical polishing method of polishing a material to be polished of a semiconductor device with a polishing pad on a polishing surface plate, by contacting and relatively moving the polishing pad and the material to be polished while supplying a metal-polishing composition to the polishing pad,

the metal-polishing composition comprising (a) a compound represented by the following Formula A, (b) a compound represented by the following Formula B, (c) an abrasive grain, and (d) an oxidizing agent:

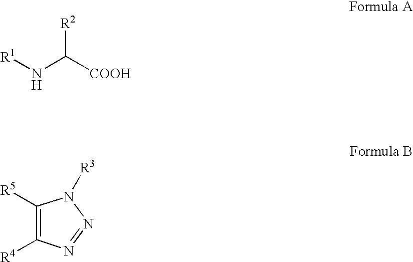

in Formula A, R¹ represents an alkyl group having 1 to 3 carbon atoms; and R² represents a hydrogen atom or an alkyl group having 1 to 4 carbon atoms, and in Formula B, R³, R⁴, and R⁵ each independently represent a hydrogen atom, or an alkyl, aryl, alkoxy, amino, aminoalkyl, hydroxy, hydroxyalkyl, or carboxy group.

### DETAILED DESCRIPTION

After intensive studies under the circumstances above, the inventors have found that it was possible to solve the problems above by using a particular amino acid and a nitrogen-containing heterocyclic compound that could inhibit solubilization of copper without deterioration in polishing rate in combination, and completed the invention.

[Metal-Polishing Composition]

The metal-polishing composition according to the invention contains (a) a compound represented by Formula A, (b) a compound represented by Formula B, (c) an abrasive grain, and (d) an oxidizing agent.

The composition may contain other compounds as needed.

The metal-polishing composition according to the invention is normally a slurry of (c) the abrasive grain dispersed in an aqueous solution containing the components above.

The metal-polishing composition according to the invention is useful as a polishing composition for use in chemical mechanical polishing for the subjects to be polished used in production of semiconductor devices.

In a favorable exemplary embodiment of the metal-polishing composition according to the invention, preferably the content of the abrasive grain is lower, and it is specifically, less than 1.0 wt %, more preferably in the range of 0.01 to 0.5 wt % in the composition.

In the invention, it is possible to obtain favorable polishing efficiency without deterioration in polishing rate by combined use of a particular amino acid and a nitrogen-containing heterocyclic compound, and thus, it is possible advantageously to obtain desirable polishing properties in addition to preventing the corrosion defect of copper wire caused by the metal-polishing composition, to reduce the scratches due to the abrasive grain, even if the content of the abrasive grain is low.

Respective components for the metal-polishing composition will be described below in detail, and the components may be used alone or in combination of two or more.

The metal-polishing composition (hereinafter, referred to also as “polishing composition”) according to the invention includes the composition (concentration) for use in polishing and also the concentrated composition that is diluted as needed before use, unless specified. The concentrated solution is diluted with water or an aqueous solution when using in polishing, and the dilution rate is generally 1 to 20 times by volume.

### <(a) Compound Represented by Formula A>

The polishing composition according to the invention contains (a) a compound represented by the following Formula A as the essential component. As apparent from the following structure, the compound is an amino acid compound having a particular structure.

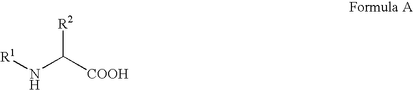

In Formula A, R¹ represents an alkyl group having 1 to 3 carbon atoms. The alkyl group may have substituents.

R¹ may be a linear, branched or cyclic alkyl group, and is preferably a methyl or ethyl group.

R² represents a hydrogen atom or an alkyl group having 1 to 4 carbon atoms. The alkyl group may be a linear or branched group. When R represents an alkyl group, the alkyl group may have one or more substituent groups, and the substituent groups that may be introduced are not particularly limited, but including the groups shown below.

Examples thereof include halogen atoms (for example, chlorine atom, bromine atom, and iodine atom); alkenyl groups [linear, branched, and cyclic substituted or unsubstituted alkenyl groups, including alkenyl groups (preferably substituted or unsubstituted alkenyl groups having 2 to 30 carbon atoms such as vinyl, allyl, prenyl, geranyl, and oleyl), cycloalkenyl groups (preferably substituted or unsubstituted cycloalkenyl group having 3 to 30 carbon atoms, i.e., monovalent groups obtained by eliminating one hydrogen atom from a cycloalkene having 3 to 30 carbon atoms such as 2-cyclopenten-1-yl, 2-cyclohexen-1-yl), and bicycloalkenyl groups (substituted or unsubstituted bicycloalkenyl group, preferably substituted or unsubstituted bicycloalkenyl groups having 5 to 30 carbon atoms, i.e., monovalent groups obtained by eliminating one hydrogen atom from a bicycloalkene having one double bond such as such as bicyclo[2,2,1]hept-2-en-1-yl and bicyclo[2,2,2]oct-2-en-4-yl)]; alkynyl groups (preferably substituted or unsubstituted alkynyl group having 2 to 30 carbon atoms, such as ethynyl, propargyl, and trimethylsilylethynyl); aryl groups (preferably substituted or unsubstituted aryl groups having 6 to 30 carbon atoms, such as phenyl, p-tolyl, naphthyl, m-chlorophenyl, and o-hexadecanoylaminophenyl); heterocyclic groups (preferably monovalent groups obtained by eliminating one hydrogen atom from a five- or six-membered substituted or unsubstituted aromatic or non-aromatic heterocyclic compound, more preferably five- or six-membered aromatic heterocyclic groups having 3 to 30 carbon atoms, such as 2-furyl, 2-thienyl, 2-pyrimidinyl, and 2-benzothiazolyl); a cyano group; a hydroxyl group; a nitro group; a carboxyl group; alkoxy groups (preferably substituted or unsubstituted alkoxy groups having 1 to 30 carbon atoms, such as methoxy, ethoxy, isopropoxy, t-butoxy, n-octyloxy, and 2-methoxyethoxy);

aryloxy groups (preferably substituted or unsubstituted aryloxy groups having 6 to 30 carbon atoms, such as phenoxy, 2-methylphenoxy, 4-t-butylphenoxy, 3-nitro phenoxy, and 2-tetradecanoylaminophenoxy); silyloxy groups (preferably silyloxy groups having 3 to 20 carbon atoms, such as trimethylsilyloxy and t-butyldimethylsilyloxy); heterocyclic oxy groups (preferably substituted or unsubstituted heterocyclic oxy groups having 2 to 30 carbon atoms, such as 1-phenyltetrazole-5-oxy and 2-tetrahydropyranyloxy); acyloxy groups (preferably a formyloxy group, substituted or unsubstituted alkylcarbonyloxy groups having 2 to 30 carbon atoms, and substituted or unsubstituted arylcarbonyloxy groups having 6 to 30 carbon atoms, such as formyloxy, acetyloxy, pivaloyloxy, stearoyloxy, benzoyloxy, and p-methoxyphenylcarbonyloxy); carbamoyloxy groups (preferably substituted or unsubstituted carbamoyloxy groups having 1 to 30 carbon atoms, such as N,N-dimethylcarbamoyloxy, N,N-diethylcarbamoyloxy, morpholinocarbonyloxy, N,N-di-n-octylaminocarbonyloxy, and N-n-octylcarbamoyloxy); alkoxycarbonyloxy groups (preferably substituted or unsubstituted alkoxycarbonyloxy groups having 2 to 30 carbon atoms, such as methoxycarbonyloxy, ethoxycarbonyloxy, t-butoxycarbonyloxy, and n-octylcarbonyloxy); aryloxycarbonyloxy groups (preferably substituted or unsubstituted aryloxycarbonyloxy group having 7 to 30 carbon atoms, such as phenoxycarbonyloxy, p-methoxyphenoxycarbonyloxy, and p-n-hexadecyloxyphenoxycarbonyloxy);

amino groups (preferably an amino group, substituted or unsubstituted alkylamino groups having 1 to 30 carbon atoms, and substituted or unsubstituted anilino groups having 6 to 30 carbon atoms, such as amino, methylamino, dimethylamino, anilino, N-methyl-anilino, and diphenylamino); ammonio groups (preferably an ammonio group and ammonio groups substituted with substituted or unsubstituted alkyl, aryl, or heterocyclic rings having 1 to 30 carbon atoms, such as trimethylammonio, triethylammonio, and diphenylmethylammonio); acylamino groups (preferably, a formylamino group, substituted or unsubstituted alkylcarbonylamino groups having 1 to 30 carbon atoms, and substituted or unsubstituted arylcarbonylamino groups having 6 to 30 carbon atoms, such as formylamino, acetylamino, pivaloylamino, lauroylamino, benzoylamino, and 3,4,5-tri-n-octyloxyphenylcarbonylamino); aminocarbonylamino groups (preferably substituted or unsubstituted aminocarbonylamino groups having 1 to 30 carbon atoms, such as carbamoylamino, N,N-dimethylaminocarbonylamino, N,N-diethylaminocarbonylamino, and morpholinocarbonylamino); alkoxycarbonylamino groups (preferably substituted or unsubstituted alkoxycarbonylamino groups having 2 to 30 carbon atoms, such as methoxycarbonylamino, ethoxycarbonylamino, t-butoxycarbonylamino, n-octadecyloxycarbonylamino, and N-methyl-methoxycarbonylamino); aryloxycarbonylamino groups (preferably substituted or unsubstituted aryloxycarbonylamino groups having 7 to 30 carbon atoms, such as phenoxycarbonylamino, p-chlorophenoxycarbonylamino, and m-n-octyloxyphenoxycarbonylamino); sulfamoylamino groups (preferably substituted or unsubstituted sulfamoylamino groups having 0 to 30 carbon atoms, such as sulfamoylamino, N,N-dimethylaminosulfonylamino, and N-n-octylaminosulfonylamino); alkyl and arylsulfonylamino groups (preferably substituted or unsubstituted alkylsulfonylamino groups having 1 to 30 carbon atoms and substituted or unsubstituted arylsulfonylamino groups having 6 to 30 carbon atoms, such as methylsulfonylamino, butylsulfonylamino, phenylsulfonylamino, 2,3,5-trichlorophenylsulfonylamino, and p-methylphenylsulfonylamino); a mercapto group; alkylthio groups (preferably substituted or unsubstituted alkylthio groups having 1 to 30 carbon atoms, such as methylthio, ethylthio, and n-hexadecylthio); arylthio groups (preferably substituted or unsubstituted arylthio groups having 6 to 30 carbon atoms, such as phenylthio, p-chlorophenylthio, and m-methoxyphenylthio); heterocyclic thio groups (preferably substituted or unsubstituted heterocyclic thio groups having 2 to 30 carbon atoms, such as 2-benzothiazolylthio and 1-phenyltetrazol-5-ylthio);

sulfamoyl groups (preferably substituted or unsubstituted sulfamoyl groups having 0 to 30 carbon atoms, such as N-ethylsulfamoyl, N-(3-dodecyloxypropyl)sulfamoyl, N,N-dimethylsulfamoyl, N-acetylsulfamoyl, N-benzoylsulfamoyl, and N-(N′-pheylcarbamoyl)sulfamoyl); a sulfo group; alkyl and arylsulfinyl groups (preferably substituted or unsubstituted alkylsulfinyl group having 1 to 30 carbon atoms and substituted or unsubstituted arylsulfinyl groups having 6 to 30 carbon atoms, such as methylsulfinyl, ethylsulfinyl, phenylsulfinyl, and p-methylphenylsulfinyl); alkyl and arylsulfonyl groups (preferably substituted or unsubstituted alkylsulfonyl group having 1 to 30 carbon atoms and substituted or unsubstituted arylsulfonyl group having 6 to 30 carbon atoms, such as methylsulfonyl, ethylsulfonyl, phenylsulfonyl, and p-methylphenylsulfonyl); acyl groups (preferably a formyl group, substituted or unsubstituted alkylcarbonyl groups having 2 to 30 carbon atoms, substituted or unsubstituted aryloxycarbonyl groups having 7 to 30 carbon atoms, and heterocyclic carbonyl groups having 4 to 30 carbon atoms bound to a carbonyl group with a substituted or unsubstituted carbon atom such as acetyl, pivaloyl, 2-chloroacetyl, stearoyl, benzoyl, p-n-octyloxyphenylcarbonyl, 2-pyridylcarbonyl, and 2-furylcarbonyl); aryloxycarbonyl groups (preferably substituted or unsubstituted aryloxycarbonyl groups having 7 to 30 carbon atoms, such as phenoxycarbonyl, o-chlorophenoxycarbonyl, m-nitro phenoxycarbonyl, and p-t-butylphenoxycarbonyl); alkoxycarbonyl groups (preferably substituted or unsubstituted alkoxycarbonyl group having 2 to 30 carbon atoms, such as methoxycarbonyl, ethoxycarbonyl, t-butoxycarbonyl, and n-octadecyloxycarbonyl); carbamoyl groups (preferably substituted or unsubstituted carbamoyl groups having 1 to 30 carbon atoms, such as carbamoyl, N-methylcarbamoyl, N,N-dimethylcarbamoyl, N,N-di-n-octylcarbamoyl, and N-(methylsulfonyl)carbamoyl); aryl and heterocyclic azo groups (preferably substituted or unsubstituted arylazo groups having 6 to 30 carbon atoms and substituted or unsubstituted heterocyclic azo groups having 3 to 30 carbon atoms, such as phenylazo, p-chlorophenylazo, and 5-ethylthio-1,3,4-thiadiazol-2-ylazo); imido groups (preferably N-succinimido and N-phthalimido);

phosphino groups (preferably substituted or unsubstituted phosphino groups having 2 to 30 carbon atoms, such as dimethylphosphino, diphenylphosphino, and methylphenoxyphosphino); phosphinyl groups (preferably substituted or unsubstituted phosphinyl groups having 2 to 30 carbon atoms, such as phosphinyl, dioctyloxyphosphinyl, and diethoxyphosphinyl); phosphinyloxy groups (preferably substituted or unsubstituted phosphinyloxy groups having 2 to 30 carbon atoms, such as diphenoxyphosphinyloxy and dioctyloxyphosphinyloxy); phosphinylamino groups (preferably substituted or unsubstituted phosphinylamino groups having 2 to 30 carbon atoms, such as dimethoxyphosphinylamino and dimethylaminophosphinylamino); a phospho group; silyl groups (preferably substituted or unsubstituted silyl groups having 3 to 30 carbon atoms, such as trimethylsilyl, t-butyldimethylsilyl, and phenyldimethylsilyl); and hydrazino groups (preferably substituted or unsubstituted hydrazino groups having 0 to 30 carbon atoms, such as trimethylhydrazino), and the like. The substituents above containing hydrogen atoms may be substituted with one of the groups similar to those described above, replacing the hydrogen atoms. Examples of such substituents include alkylcarbonylaminosulfonyl groups, arylcarbonylaminosulfonyl groups, alkylsulfonylaminocarbonyl groups, and arylsulfonylaminocarbonyl groups, and specific examples thereof include methylsulfonylaminocarbonyl, p-methylphenylsulfonylaminocarbonyl, acetylaminosulfonyl, and benzoylaminosulfonyl groups, and the like. These substituents may be further substituted.

The alkyl group in the substituents described above, for example the alkyl group in the alkylthio group, is an alkyl group in the concept described below. Namely, it represents, for example, a linear, branched or cyclic, substituted or unsubstituted alkyl group. It is an alkyl group (preferably an alkyl group having 1 to 30 carbon atoms, such as methyl, ethyl, n-propyl, isopropyl, t-butyl, n-octyl, eicosyl, 2-chloroethyl, 2-cyanoethyl, or 2-ethylhexyl), a cycloalkyl group (preferably a substituted or unsubstituted cycloalkyl group having 3 to 30 carbon atoms, such as cyclohexyl, cyclopentyl, or 4-n-dodecylcyclohexyl), or a bicycloalkyl group (preferably a substituted or unsubstituted bicycloalkyl group having 5 to 30 carbon atoms, i.e., a monovalent group obtained by eliminating a hydrogen atom from a bicycloalkane having 5 to 30 carbon atoms, such as bicyclo[1,2,2]heptan-2-yl, bicyclo[2,2,2]octan-3-yl), and the alkyl group may have a tricyclo structure with an additional ring structure.

Favorable examples of the substituents introduced into R² include aryl groups, heterocyclic groups, a hydroxyl group, a nitro group, a carboxyl group, alkoxy groups, aryloxy groups, heterocyclic oxy groups, amino groups, acylamino groups, aminocarbonylamino groups, alkoxycarbonylamino groups, aryloxycarbonylamino groups, sulfamoylamino groups, alkylsulfonylamino groups, arylsulfonylamino groups, sulfamoyl groups, a sulfo group, acyl groups, and carbamoyl groups, more preferably, a phenyl group, a hydroxy group, hydroxyalkyl groups, a carboxyl group, carboxyalkyl groups, a sulfo group, carbamoyl groups, amido groups, amino groups, a methoxy group, a sulfo group, sulfamoyl groups, and the like, more preferably, a hydroxyl group, a carboxyl group, alkoxy groups and carbamoyl groups.

Specific favorable compounds represented by Formula A include the followings: N-methylglycine, N-ethylglycine, n-propylglycine, N-methylalanine, N-ethylalanine, N-propylalanine, N-methylserine, N-ethylserine, N-propylserine, N-methylthreonine, N-ethylthreonine, N-propylthreonine, N-methylasparagine, N-ethylasparagine, N-propylasparagine, N-methylaspartic acid, N-ethylaspartic acid, N-propylaspartic acid, N-methylglutamine, N-ethylglutamine, N-propylglutamine, N-methylglutamic acid, N-ethylglutamic acid, N-propylglutamic acid, N-methylvaline, N-ethylvaline, N-propylvaline, N-methylleucine, N-ethylleucine, N-propylleucine, N-methylphenylalanine, N-ethylphenylalanine, N-propylphenylalanine, N-methyllysine, N-ethyllysine, N-propyllysine, and the like.

Among them, N-methylglycine, N-ethylglycine, N-methylasparagine, N-methylglutamine, and N-methylthreonine are preferable. These compounds represented by Formula A may be used alone or in combination of two or more in the polishing composition.

The amount of the compound (a) represented by Formula A added to the polishing composition is preferably 0.1 wt % or more and 5 wt % or less, more preferably, 0.5 wt % or more and 2.5 wt % or less, for improvement in anti-dishing efficiency.

<(b) Compound Represented by Formula B >

The polishing composition according to the invention contains (b) a compound represented by the following Formula B as the essential component. As apparent from the following structure, the compound is a triazole compound having a particular structure.

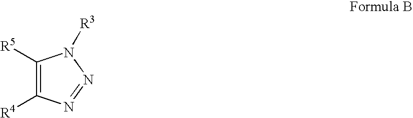

In Formula B, R³, R⁴, and R⁵ each independently represent a hydrogen atom, or an alkyl, aryl, alkoxy, amino, aminoalkyl, hydroxy, hydroxyalkyl, carboxy, carboxyalkyl or carbamoyl group. If R³, R⁴, or R⁵ is a substituent other than a hydrogen atom, the group may be substituted additionally, and the substituents that may be introduced include alkyl groups, a phenyl group, a hydroxy group, a carboxyl group, a sulfo group, carbamoyl groups, amido groups, amino groups, a methoxy group and the like.

Specific favorable compounds represented by Formula B are listed below.
1,2,3-Triazole
1,2,3-Triazole-4-carboxylic acid
5-Methyl-1,2,3-triazole-4-carboxylic acid
1,2,3-Triazole-4,5-dicarboxylic acid
1-Aminoethyl-1,2,3-triazole
1-Methanol-1,2,3-triazole
1-Ethanol-1,2,3-triazole
1-Amino-5-n-propyl-1,2,3-triazole,
1-(β-Aminoethyl)-1,2,3-triazole,
1-(3-Aminopropyl)-1,2,3-triazole
4-Hexyl-1,2,3-triazole
4-Phenyl-1,2,3-triazole
4-Aminomethyl-1,2,3-triazole
4-Aminoethyl-1,2,3-triazole
4-Methanol-1,2,3-triazole
4-Ethanol-1,2,3-triazole
4-Amino-5-n-propyl-1,2,3-triazole,
4-(β-Aminoethyl)-1,2,3-triazole,
4-(3-Aminopropyl)-1,2,3-triazole
1-Methyl-1,2,3-triazole
1-Acetic acid-1,2,3-triazole
1-Amino-1,2,3-triazole,
1-Amino-5-methyl-1,2,3-triazole,
4,5-Dimethyl-1,2,3-triazole,
4-Phenyl-1,2,3-triazole,
1,2,3-Triazole
1,2,3-Triazole-4-carboxylic acid
1,2,3-Triazole-5-methyl-4-carboxylic acid
1,2,3-Triazole-4,5-dicarboxylic acid
1,2,3-Triazole-4-sulfonic acid
1,2,3-Triazole-4-ol
1,2,3-Triazole-4,5-diol
1,2,3-Triazole-4-carboxamide
1,2,3-Triazole-4-carboxamic acid
1,2,3-Triazole-4-amine
1,2,3-Triazole-5-hydroxy-4-carboxylic acid
1,2,3-Triazole-5-isopropyl-4-carboxylic acid
1,2,3-Triazole-4-acetic acid
1,2,3-Triazole-5-carboxymethyl-4-carboxylic acid
4-Methyl-1,2,3-triazole
4-Ethyl-1,2,3-triazole
4-n-Propyl-1,2,3-triazole
4-Isopropyl-1,2,3-triazole
4-n-Butyl-1,2,3-triazole
4-t-Butyl-1,2,3-triazole
4-n-Pentyl-1,2,3-triazole
4-n-Hexyl-1,2,3-triazole
4,5-Dimethyl-1,2,3-triazole
4-Phenyl-1,2,3-triazole
4-Aminomethyl-1,2,3-triazole
4-Aminoethyl-1,2,3-triazole
4-(3-Aminopropyl)-1,2,3-triazole
4-Methanol-1,2,3-triazole
4-(1-Ethanol)-1,2,3-triazole
4-(2-Ethanol)-1,2,3-triazole
4-(3-Propan-1-ol)-1,2,3-triazole
4-(1-Propan-2-ol)-1,2,3-triazole
4-(2-Propan-2-ol)-1,2,3-triazole
4-(1-Butane-1-ol)-1,2,3-triazole
4-(1-Hexane-1-ol)-1,2,3-triazole
4-(1-Cyclohexanol)-1,2,3-triazole
4-(4-Methyl-2-pentane-2-ol)-1,2,3-triazole
4-amino-5-n-propyl-1,2,3-triazole
4-Methoxymethyl-1,2,3-triazole
4-Diethoxymethyl-1,2,3-triazole
4-Acetyl-1,2,3-triazole
4-Benzylsulfonyl-1,2,3-triazole
4,5-Dihydroxymethyl-1,2,3-triazole
5-Amino-4-carboxy-1,2,3-triazole
5-Amino-4-carboxamido-1,2,3-triazole
1-Aminoethyl-1,2,3-triazole
1-Methanol-1,2,3-triazole
1-Ethanol-1,2,3-triazole
1-Amino-5-n-propyl-1,2,3-triazole
1-(3-Aminopropyl)-1,2,3-triazole
1-Methyl-1,2,3-triazole
1-Acetic acid-1,2,3-triazole
1-Amino-1,2,3-triazole
1-Amino-5-methyl-1,2,3-triazole

Among them, 1,2,3-triazole, 1,2,3-triazole-4-carboxylic acid, and 5-methyl-1,2,3-triazole-4-carboxylic acid, for example, are favorable.

These compounds represented by Formula B may be used alone or in combination of two or more in the polishing composition.

The amount of (b) the compound represented by Formula B added to the polishing composition is preferably 0.0001 wt % or more and 0.01 wt % or less, more preferably 0.0005 wt % or more and 0.007 wt % or less, from the viewpoint of polishing rate.

<(c) Abrasive Grain>

The polishing composition according to the invention contains an abrasive grain. Examples of the favorable abrasive grains include silicas (sedimentation silica, fumed silica, colloidal silica, and synthetic silica), ceria, alumina, titania, zirconia, germania, manganese oxide, and the like, and colloidal silica is particularly preferable. The colloidal silica favorably used as abrasive grain is prepared, for example, by hydrolysis of a silicon alkoxide compound such as Si(OC₂H₅)₄, Si(sec-OC₄H₉)₄, Si(OCH₃)₄, and Si(OC₄H₉)₄ in the sol-gel process, and the colloidal particles thus obtained have very narrow particle size distribution.

The primary particle diameter of abrasive grain is the particle diameter at the 50% cumulative number in a cumulative particle diameter curve plotted between the particle diameter of abrasive grain and the cumulative number of the particles having the particle diameter. For example, LB-500 manufactured by Horiba, Ltd. is used as a measurement device to find particle size distribution.

The primary particle diameter may be used as it is when the abrasive grain particle is spherical, but the size of an undefined-shape particle is expressed by the diameter of a sphere having the same volume. The particle size can be determined by a known method such as photon correlation method, laser diffraction method, or Coulter Counter method, but in the invention, used is a method of determining the shape and size of an individual particle by observing under a scanning microscope or taking a transmission electron microscope by replica method and calculating the particle size therefrom. Specifically, the volume of individual particle is calculated form the projected area of a particle and the thickness of the particle, as determined from the shadow of its replica, with reference to a diffraction grating with a already known length. In such a case, it is desirable to measure 500 or more particles and determine the volume statistically, although the number may vary according to the particle size distribution. The method, which is described in detail in JP-A No. 2001-75222, paragraph number [0024], is also applicable to the invention.

The average diameter (primary particle diameter) of the abrasive grain contained in the polishing composition according to the invention is preferably in the range of 20 to 70 nm, more preferably in the range of 20 to 50 nm. Particles of 5 nm or more are desirable for obtaining sufficient polishing processing rate. The particle diameter is preferably 50 nm or less, for prevention of excessive frictional heating during polishing processing.

It is also possible to use organic polymer particles together with the common inorganic abrasive grain described above, in the range that does not impair the advantageous effects of the invention. In addition, various surface-treated colloidal silicas, such as colloidal silica surface-modified with aluminate or borate ion and surface potential-controlled colloidal silica, composite abrasive grains containing multiple materials, and the like may also be used additionally, according to applications.

In the invention, the additive amount of (c) the abrasive grain is determined properly according to applications, but is generally in the range of 0.001 to 20 wt % with respect to the total weight in the metal-polishing solution composition. In the invention, it is possible to have excellent polishing efficiency even at a abrasive grain additive amount of less than 1.0 wt %, because of the influence by addition of the components (a) and (b), and thus, the additive amount of the abrasive grain is preferably less than 1.0 wt %, more preferably in the range of 0.01 to 0.5 wt %, for prevention of the scratching by abrasive grain.

<(d) Oxidizing Agent>

The polishing composition according to the invention contains a compound (oxidizing agent) oxidizing the metal favorably to be polished.

Examples of the oxidizing agents include hydrogen peroxide, peroxides, nitrate salts, iodate salts, periodate salts, hypochlorite salts, chlorite salts, chlorate salts, perchlorate salts, persulfate acid salts, dichromate salts, permanganate salts, ozone water, silver (II) salts, and iron (III) salts. Favorable examples of the iron (III) salts include inorganic iron (III) salts such as iron nitrate (III), iron chloride (III), iron sulfate (III), and iron bromide (III), and organic iron (III) complex salts.

When an organic iron (III) complex salt is used, examples of the complex-forming compounds for the iron (III) complex salt include acetic acid, citric acid, oxalic acid, salicylic acid, diethyldithiocarbaminc acid, succinic acid, tartaric acid, glycolic acid, glycine, alanine, aspartic acid, thioglycol acid, ethylenediamine, trimethylenediamine, diethylene glycol, triethylene glycol, 1,2-ethanedithiol, malonic acid, glutaric acid, 3-hydroxybutyric acid, propionic acid, phthalic acid, isophthalic acid, 3-hydroxysalicylic acid, 3,5-dihydroxysalicylic acid, gallic acid, benzoic acid, maleic acid, the salts thereof, and aminopolycarboxylic acids and the salts thereof

Examples of the amino polycarboxylic acid and the salts thereof include ethylenediamine-N,N,N′,N′-tetraacetic acid, diethylenetriaminepentaacetic acid, 1,3-diaminopropane-N,N,N′,N′-tetraacetic acid, 1,2-diaminopropane-N,N,N′,N′-tetraacetic acid, ethylenediamine-N,N′-disuccinic acid (racemic body), ethylenediaminedisuccinic acid (SS isomer), N-(2-carboxylatoethyl)-L-aspartic acid, N-(carboxymethyl)-L-aspartic acid, β-alaninediacetic acid, methyliminodiacetic acid, nitrilotriacetic acid, cyclohexanediaminetetraacetic acid, iminodiacetic acid, glycol ether diamine-tetraacetic acid, ethylenediamine-1-N,N′-diacetic acid, ethylenediamine-ortho-hydroxyphenylacetic acid, N,N-bis(2-hydroxybenzyl)ethylenediamine-N,N-diacetic acid, and the like, and the salts thereof The counter salt is preferably an alkali-metal salt or an ammonium salt, particularly preferably an ammonium salt.

In particular, hydrogen peroxide, iodate salts, hypochlorite salts, chlorate salts, persulfate salts, and organic iron (III) complex salts are preferable; when an organic iron (III) organic complex salt is used, favorable complex-forming compounds include citric acid, tartaric acid, aminopolycarboxylic acid (specifically, ethylenediamine-N,N,N′,N′-tetraacetic acid, diethylenetriamine pentaacetic acid, 1,3-diaminopropane-N,N,N′,N′-tetraacetic acid, ethylenediamine-N,N′-disuccinic acid (racemic body), ethylenediamine disuccinic acid (SS isomer), N-(2-carboxylatoethyl)-L-aspartic acid, N-(carboxymethyl)-L-aspartic acid, β-alanine diacetic acid, methyliminodiacetic acid, nitrilotriacetic acid, and iminodiacetic acid). Among the oxidizing agents above, hydrogen peroxide, persulfate salts, and iron (III) ethylenediamine-N,N,N′,N′-tetraacetate, and the complexes of 1,3-diaminopropane-N,N,N′,N′-tetraacetic acid and ethylenediaminedisuccinic acid (SS isomer) are most favorable.

The additive amount of (d) the oxidizing agent is preferably 0.003 mol to 8 mol, more preferably 0.03 mol to 6 mol, and particularly more preferably 0. 1 mol to 4 mol, per L of the polishing composition used for polishing. The additive amount of the oxidizing agent is preferably 0.003 mol or more for assuring a CMP rate oxidizing the metal sufficiently and 8 mol or less for prevention of roughening of the polishing face.

<(e) Nitrogen-Containing Heterocyclic Compound Selected from 1,2,3,4-tetrazole and the derivatives thereof>

The polishing composition according to the invention contains a nitrogen-containing heterocyclic compound having a particular structure as the component (b), but preferably contains additionally a nitrogen-containing heterocyclic compound selected from (e) 1,2,3,4-tetrazole and the derivatives thereof as the other nitrogen-containing heterocyclic compound. Combined used of the component (e) inhibits undesirable adhesion of the abrasive grain on the polishing surface effectively.

The nitrogen-containing heterocyclic compound (e) selected from 1,2,3,4-tetrazole and the derivatives thereof more preferably contains an anionic substituent group in the molecule. Such a nitrogen-containing heterocyclic compound is a compound having four or more nitrogen atoms in the molecule.

Examples of the anionic substituents include carboxyl, sulfo, hydroxyl, amino, carbamoyl, carbonamido, sulfamoyl, sulfonamido and in particular, carboxyl and sulfo groups are preferable, and a carboxyl group is most preferable. The 1,2,3,4-tetrazole or the derivative thereof is preferably a compound having no substituent on the nitrogen atom forming the tetrazole ring and having the anionic substituent described above at the tetrazole 5 position.

Examples thereof include, but are not limited to, the following exemplary compounds (I-1) to (I-16), such as 1,2,3,4-tetrazole, 5-amino-1,2,3,4-tetrazole, and 5-methyl-1,2,3,4-tetrazole.

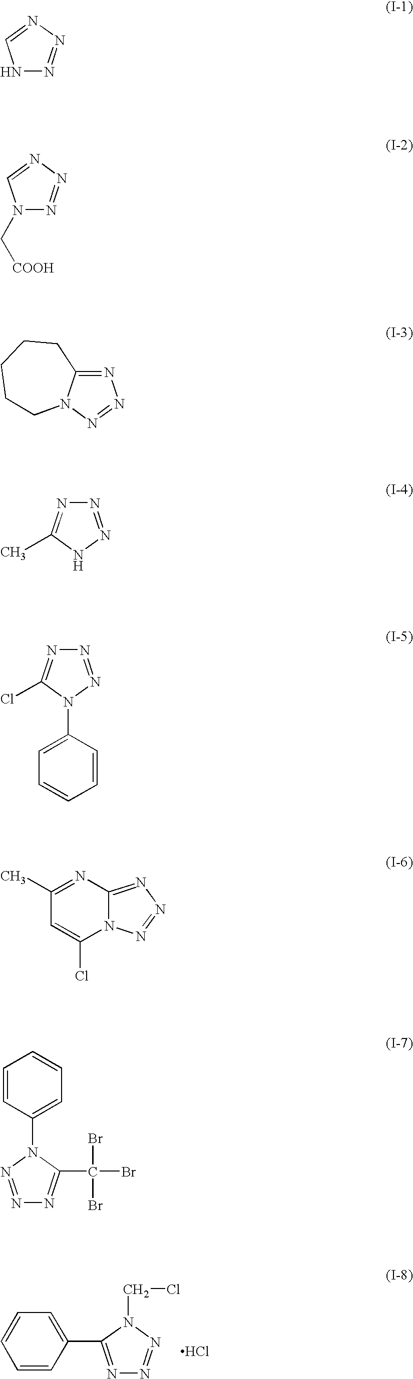

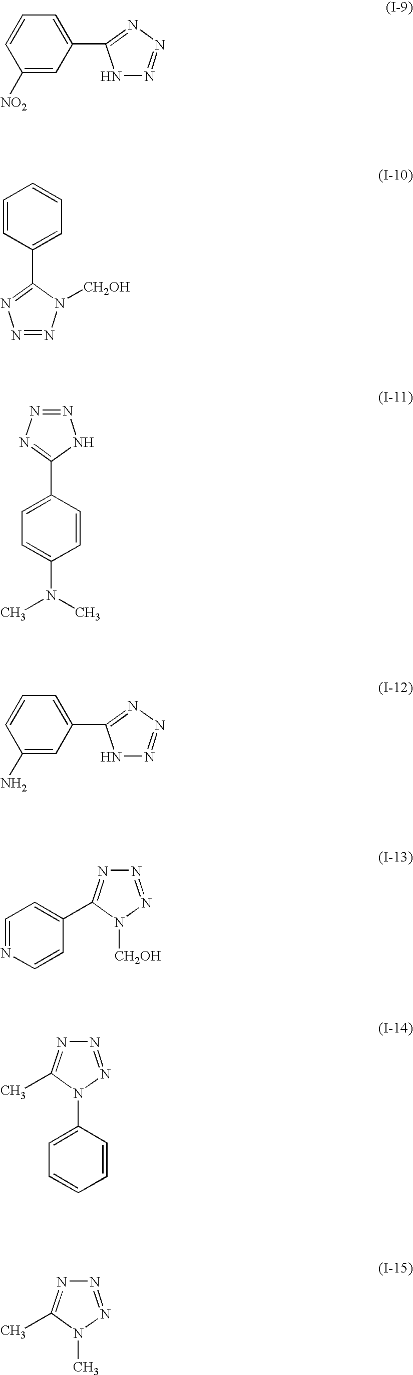

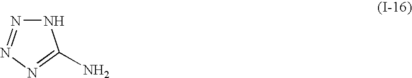

In particular, exemplary compounds (I-1), (1-2) to (I-4), and (I-6) to (I-16) having an anionic substituent in the molecule are preferable.

These components (e) may be used alone or in combination of two or more. The additive amount of the nitrogen-containing heterocyclic compound, selected from (e) 1,2,3,4-tetrazole and the derivatives thereof, used as needed in the polishing composition according to the invention is preferably, 0.0001 wt % or more and 0.005 wt % or less, more preferably 0.0005 wt % or more and 0.002 wt % or less.

The polishing composition according to the invention may contain the following components as needed, in addition to the components described above. Hereinafter, other components added optionally to the polishing composition according to the invention will be described.

<(f) Surfactant and/or Hydrophilic Polymer>

The polishing composition according to the invention may contain a surfactant and/or a hydrophilic polymer (f).

The surfactant and/or hydrophilic polymer is preferably in the acid type, and, if it is in the salt structure, it is preferably a ammonium salt, potassium salt, sodium salt, or the like, particularly preferably an ammonium or potassium salt.

Both the surfactant and the hydrophilic polymer have an action to reduce the contact angle on the polishing face and to facilitate uniform polishing. The surfactant and/or the hydrophilic polymer for use are selected favorably from the following group of surfactants.

Anionic surfactants include carboxylate salts, sulfonate salts, sulfate ester salts, and phosphate ester salts: carboxylate salts including soaps, N-acylamino acid salts, polyoxyethylene or polyoxypropylene alkylether carboxylate salts, and acylated peptides; sulfonate salts including alkylsulfonate salts, alkylbenzene and alkylnaphthalenesulfonate salts, naphthalenesulfonate salts, (alkyl)formalin naphthalenesulfonate condensates, (alkyl)formalin naphthalenesulfonate condensates, sulfoscuccinate salts, α-olefin sulfonate salts, and N-acyl sulfonate salts; sulfate ester salts including sulfated oils, alkyl sulfate salts, alkylether sulfate salts, polyoxyethylene or polyoxypropylene alkylallylether sulfate salts, and alkyl amide sulfate salts; and phosphate ester salts including alkylphosphate salts and polyoxyethylene or polyoxypropylene alkylallylether phosphate salts.

Cationic surfactants include aliphatic amine salts, aliphatic quaternary ammonium salts, benzalkonium chloride salt, benzethonium chloride, pyridinium salts, and imidazolinium salts; and amphoteric surfactants include carboxybetaine-type, sulfobetaine type, aminocarboxylate salts, imidazolinium betaines, lecithins, and alkylamine oxides. Nonionic surfactants include ether-type, ether ester-type, ester-type, nitrogen-containing-type; ether-type surfactants including polyoxyethylene alkyl and alkylphenylethers, alkyl allyl formaldehyde-condensed polyoxyethylene ethers, polyoxyethylene polyoxypropylene block polymer, and polyoxyethylene polyoxypropylene alkylethers; ether ester-type surfactants including glycerin ester polyoxyethylene ether, sorbitan ester polyoxyethylene ether, and sorbitol ester polyoxyethylene ether; ester-type surfactants including polyethylene glycol fatty acid esters, glycerin esters, polyglycerin esters, sorbitan esters, propylene glycol esters, and sucrose esters; nitrogen-containing surfactants including fatty acid alkanol amides, polyoxyethylene fatty acid amides, and polyoxyethylene alkyl amides; and the like. In addition, fluorochemical surfactants, silicone-based surfactant and others are also included.

Also included are ethers including polyethylene glycol, polypropylene glycol, polytetramethylene glycol, polyethylene glycol alkylethers, polyethylene glycol alkenylethers, alkylpolyethylene glycols, alkylpolyethylene glycol alkylethers, alkylpolyethylene glycol alkenylethers, alkenylpolyethylene glycols, alkenylpolyethylene glycol alkylethers, alkenylpolyethylene glycol alkenylethers, polypropylene glycol alkylethers, polypropylene glycol alkenylethers, alkylpolypropylene glycols, alkylpolypropylene glycol alkylethers, alkylpolypropylene glycol alkenylethers, alkenylpolypropylene glycols, alkenylpolypropylene glycol alkylethers and alkenylpolypropylene glycol alkenylethers; polysaccharides such as alginic acid, pectinic acid, carboxymethylcellulose, curdlan and pullulan; amino acid salts; polycarboxylic acids and the salts thereof, such as polyaspartic acid, polyglutamic acid, polylysine, polymalic acid, polymethacrylic acid, ammonium polymethacrylate salt, sodium polymethacrylate salt, polymaleic acid, polyitaconic acid, polyfumaric acid, poly(p-styrene carboxylic acid), polyacrylic acid, polyacrylamide, aminopolyacrylamide, ammonium polyacrylate salt, sodium polyacrylate salt, polyamide acid, polyamide acid ammonium salt, polyamide acid sodium salt and polyglyoxylic acid; vinyl polymers such as polyvinylalcohol, polyvinylpyrrolidone and polyacrolein; and the like.

However, when the base substance to be processed is for example a silicon substrate for semiconductor integrated circuit, contamination with an alkali metal, alkali-earth metal, or halide is undesirable, thus, acid-type is preferable and if a salt of an acid-type surfactant is used, it is preferably the ammonium salt. The surfactant is arbitrary, if the base substance is for example glass. Among the exemplary compounds above, ammonium polyacrylate salt, polyvinylalcohol, polyvinylpyrrolidone, polyethylene glycol, and polyoxyethylene polyoxypropylene block polymers are more preferable.

The total additive amount of the surfactant and/or the hydrophilic polymer is preferably 0.001 to 1 g, more preferably 0.02 to 0.1 g, and particularly preferably 0.005 to 0.05 g, in the polishing composition per L used in polishing. Namely, the additive amount of the surfactant and/or the hydrophilic polymer is preferably 0.001 g or more for favorable effect, and 10 g or less for prevention of decrease in CMP velocity. The weight-average molecular weight of the surfactant and/or the hydrophilic polymer is preferably 500 to 100,000, particularly preferably 2,000 to 50,000.

The surfactants may be used alone or in combination of two or more, and surfactants different in kind may be used in combination.

### <(g) Amino Acid>

The polishing composition according to the invention may contain a common amino acid compound not included in (a) the component, in the range that does not impair the advantageous effects of the invention, in addition to (a) the amino acid compound represented by Formula A. At least one of the amino groups in the amino acid compound is preferably a secondary or tertiary amino group. The compound may have one or more substituents additionally.

The amino acid compound for use in the invention is preferably an amino acid or an amino polyacid, particularly preferably a compound selected from the following group of compounds:

Amino acids including glycine, hydroxyethylglycine, dihydroxyethylglycine, glycylglycine, N-methylglycine, L-alanine, β-alanine, L-2-aminobutyric acid, L-norvaline, L-valine, L-leucine, L-norleucine, L-isoleucine, L-alloisoleucine, L-phenylalanine, L-proline, sarcosine, L-ornithine, L-lysine, taurine, L-serine, L-threonine, L-allothreonine, L-homoserine, L-tyrosine, 3,5-diiodo-L-tyrosine, β-(3,4-dihydroxyphenyl)-L-alanine, L-thyroxine, 4-hydroxy-L-proline, L-cysteine, L-methionine, L-ethionine, L-lanthionine, L-cystathionine, L-cystine, L-cysteine acid, L-aspartic acid, L-glutamic acid, S-(carboxymethyl)-L-cysteine, 4-aminobutyric acid, L-asparagine, L-glutamine, azaserine, L-arginine, L-canavanine, L-citrulline, 6-hydroxy-L-lysine, creatine, L-kynurenine, L-histidine, 1-methyl-L-histidine, 3-methyl-L-histidine, ergothioneine, L-tryptophan, actinomycin C1, apamin, angiotensin I, angiotensin II and antipain. Among them, glycine, L-alanine, L-histidine, L-proline, L-lysine, and dihydroxyethylglycine are preferable.

Examples of the amino polyacids include iminodiacetic acid, hydroxyethyliminodiacetic acid, nitrilotriacetic acid, diethylenetriamine pentaacetic acid, ethylenediaminetetraacetic acid, nitrilotrismethylenephosphonic acid, ethylenediamine-N,N,N′,N′-tetramethylenesulfonic acid, trans-cyclohexanediaminetetraacetic acid, 1,2-diaminopropanetetraacetic acid, glycol ether diaminetetraacetic acid, ethylenediamine-ortho-hydroxyphenylacetic acid, ethylenediaminediscuccinic acid (SS body), N-(2-carboxylatoethyl)-L-aspartic acid, β-alaninediacetic acid, N,N′-bis(2-hydroxybenzyl)ethylenediamine-N,N′-diacetic acid, and the like.

The content of (g) the amino acid compound, other than (a) the component, used additionally in the polishing composition according to the invention is preferably 50 wt % or less with respect to (a) the component, and the total amount of (a) the components and (g) in the polishing composition is preferably 0. 1 wt % or more and 5 wt % or less, more preferably 0.5 wt % or more and 2 wt % or less.

<Phosphate or Phosphite Salt (h)>

The polishing composition according to the invention preferably contains a phosphate or phosphite salt (h), if it contains an inorganic component other than the abrasive grain.

The kind, additive amount, or pH of the components above in the polishing composition according to the invention are preferably adjusted properly according to the reactivity and the absorbency thereof on the polishing surface, the solubility of the polishing metal, the electrochemical properties of the polishing face, the dissociation state of the compound's functional group, and the stability of the liquid.

The pH of the polishing composition according to the invention is preferably in the range of 3 to 9, more preferably 3.8 to 8.0, form the point of the flattening of polishing. The pH can be controlled easily, for example, by addition of a buffer, alkali agent, or inorganic acid, as it is properly selected, as described above.

### [Raw Material for Wiring Metal]

In the invention, the semiconductor to be polished is preferably a LSI having wiring of a copper metal and/or a copper alloy, particularly preferably of a copper alloy. Among copper alloys, silver-containing copper alloys are preferable. The content of silver in the copper alloy is preferably 40 wt % or less, more preferably 10 wt % or less, still more preferably 1 wt % or less, and most advantageously in the range of 0.000001 to 0.1 wt %.

### [Wire Width]

In the invention, the half pitch is preferably 0.15 μm or less, particularly 0.10 μm or less, still more preferably 0.08 μm or less, when the semiconductor to be polished is, for example, for DRAM devices, while the half pitch is preferably 0.12 μm or less, more preferably 0.09 μm or less, and still more preferably 0.07 μm when it is for MPU devices. The polishing solution according to the invention has a particularly advantageous effect on such LSI's.

### [Barrier Metal]

In the invention, a barrier layer may be formed between the wiring of a copper metal and/or a copper alloy and an interlayer insulation film for prevention of copper diffusion in the semiconductor. The barrier layer is preferably of a low-resistance metal material; TiN, TiW, Ta, TaN, W, WN, and Ru are preferable; and in particular, Ta and TaN is particularly preferable.

### [Polishing Method]

The polishing composition according to the invention may be a concentrated solution that is diluted with water before use, a combination of aqueous solutions of respective components that are mixed and as needed diluted with water before use, or a diluted solution immediately for use.

Any polishing composition may be used in the polishing method using the polishing composition according to the invention, wherein the polishing solution is supplied to the polishing pad on a polishing surface plate and the polishing face is polished as the polishing pad is rotated relative to each other, while the polishing face is in contact with the polishing pad.

Any common polishing machine having a holder holding a semiconductor substrate having a polishing face and a polishing surface plate carrying a polishing pad connected thereto (which in turn is connected to a variable rotational frequency motor) may be used as the polishing machine.

The polishing pad is not particularly limited, and a common nonwoven fabric, expanded polyurethane, porous fluoroplastics or the like may be used. The polishing condition is not particularly limited, and the rotational velocity of the polishing surface plate is preferably low at around 200 rpm or less for prevention of separation of the substrate.

The pressure applied to the semiconductor substrate having the polishing face (film to be polished) toward the polishing pad is preferably 20 kPa or less, still more preferably 6 to 15 kPa, for favorable uniformity of the polishing rate on the wafer face and flatness of the pattern.

The polishing composition is supplied to the polishing pad continuously, for example, by a pump during polishing. The feed rate is not particularly limited, but the surface of the polishing pad is preferably coated consistently with the polishing composition. The semiconductor substrate after polishing is washed thoroughly with running water and then dried, the water droplets deposited on the semiconductor substrate is separated, for example, by using a spin drier, and use of the polishing composition according to the invention is effective in improving the washing efficiency after polishing. It is presumably because of electrostatic repulsion between the abrasive grain and the wiring metal.

The aqueous solution used for dilution in the polishing method according to the invention is the same as the following aqueous solution.

The aqueous solution is water containing at least one or more of an oxidizing agent, an acid, an additive, and a surfactant, and the components contained in the aqueous solution and the component in the polishing composition to be diluted constitute together the components in the polishing solution used during polishing.

If the polishing solution is diluted with the aqueous solution before use, a less-soluble component can be added to and dissolved in the aqueous solution, and thus, it is possible to prepare a more concentrated polishing composition.

When the concentrated polishing composition is diluted with water, for example, the concentrated polishing composition and water are mixed while the pipes thereof are connected to each other, and the diluted polishing composition is supplied to the polishing pad.

The solutions may be mixed by any one of commonly practiced methods such as a method of mixing solutions by collision while the solution are fed in a narrow passage in the pressurized state, a method of repeatedly separating and mixing solutions in a piping filled with a packing material such as glass beads, and a method of installing a externally-driven blade in the piping.

The supply rate of the polishing composition may be determined in the range of 10 to 1,000 ml/min, but, considering the physical properties of the polishing composition according to the invention, it is preferably 190 ml/min or less, more preferably in the range of 100 to 190 ml/min.

In the polishing method by using a solution of the concentrated polishing composition diluted with an aqueous solution, the piping for supply of the polishing composition and the piping for supply of water or the aqueous solution are installed independently, and particular amounts of respective solutions are supplied to the polishing pad, and polishing is performed by relative movement of the polishing pad and the polishing face.

Alternatively, particular amounts of the concentrated polishing composition and water are placed and mixed in a container, and the polishing composition after mixing is supplied to the polishing pad for polishing.

In yet another polishing method of the invention, the components to be contained in the polishing composition are divided into at least two component portions; water is added thereto for dilution before use; the mixture is supplied to the polishing pad on the polishing surface plate; and polishing is performed by relative movement of the polishing pad and the polishing face.

For example, the oxidizing agent is contained in one constituent component (A), and the acid, additive, surfactant and water is included in the other constituent component (B), and the constituent components (A) and (B) are diluted with water before use. Alternatively, a less-soluble additive is added as divided into two constituent components (A) and (B); the oxidizing agent, additive and surfactant are contained in one constituent component (A) and the acid, additive, surfactant and water in the other constituent component (B); and the constituent components (A) and (B) are diluted with water before use. In this case, three pipings for supply of the constituent components (A) and (B) and water are needed, dilution and mixing should be performed in a piping supplying the polishing solution to the polishing pad to which three pipings are connected, and in such a case, two pipings may be first connected and then, the other piping to the piping.

For example, constituent component containing a less soluble additive and another constituent component may be mixed in an elongated mixing pipe for assuring solubilization, which is connected to a water piping.

Other mixing methods include, as described above, a method of connecting three pipings directly to the polishing pad, and mixing the components by relative movement of the polishing pad and the polishing face and a method of mixing three constituent components in a container and supplying a diluted polishing composition therefrom to the polishing pad. In the polishing method described above, the one constituent component containing the oxidizing agent may be kept to 40° C. or lower and the other constituent component heated to a temperature range of room temperature to 100° C.; and the mixture of the one constituent component after dilution with the other constituent component or water may be adjusted to 40° C. or lower before use.

Increase of temperature leads to higher solubility, and thus, is effective in dissolving less soluble raw materials in the polishing composition.

Raw materials dissolved in the other component containing no oxidizing agent at a temperature in the range of room temperature to 100° C. may precipitate in the solution when cooled, and thus, it is desirable to dissolve the precipitate by heating before use of the components at lower temperature.

In such a method, used is a means of feeding the heated and dissolved constituent component solution and a means to stir the precipitate-containing solution and dissolving the precipitate in a heated pipe by feeding the solution thereto. Because when the temperature of the one constituent component containing an oxidizing agent is heated to a temperature of 40° C. or higher, the oxidizing agent may be decomposed, if the heated constituent component is mixed with a constituent component containing an oxidizing agent, the mixed solution is preferably controlled to be 40° C. or lower.

In the invention, as described above, the components for the polishing composition may be supplied to the polishing face, as they are divided into two or more portions. In such a case, an oxidizing agent-containing component and an acid-containing component are preferably supplied as separated. In addition, the polishing composition may be supplied to the polishing face as a concentrated solution, together with dilution water separately supplied.

[Pad]

The polishing pad may be a non-foamed pad or a foamed pad. The former pad is a pad of a hard synthetic-resin bulk material like a plastic plate. Alternatively, the latter pad is an independent-foam pad (dry foamed), a continuous-foam pad (wet foamed), or a two-layer composite pad (lamination), and the two-layer composite pad (laminated) is preferable. The foaming may be homogeneous or heterogeneous. The polishing pad may contain additionally a abrasive grain used for polishing (such as ceria, silica, alumina, or resin). The polishing pad may be made of a soft or hard resin, and the composite pad (laminated) preferably use resins different in hardness.

Favorable examples of the materials include nonwoven fabric, artificial leather, polyamide, polyurethane, polyester, polycarbonate, and the like.

In addition, lattice-shaped grooves, holes, concentric grooves, spiral grooves, and the like may be formed on the surface in contact with the polishing face.

[Wafer]

The wafer to be processed by CMP with the polishing composition according to the invention preferably has a diameter of 200 mm or more, more preferably 300 mm or more. The advantageous effects of the invention are more distinctive when the diameter is 300 mm or more.

Hereinafter, the exemplary embodiments of the invention will be listed.

<1> A metal-polishing composition for use in chemical mechanical polishing of semiconductor devices, comprising:

(a) a compound represented by the following Formula A, (b) a compound represented by the following Formula B, (c) an abrasive grain, and (d) an oxidizing agent:

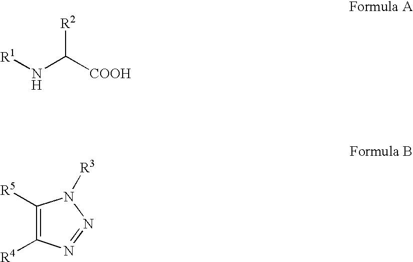

in Formula A, R¹ represents an alkyl group having 1 to 3 carbon atoms; and R² represents a hydrogen atom or an alkyl group having 1 to 4 carbon atoms, and in Formula B, R³, R⁴, and R⁵ each independently represent a hydrogen atom, or an alkyl, aryl, alkoxy, amino, aminoalkyl, hydroxy, hydroxyalkyl, carboxy, carboxyalkyl or carbamoyl group.

<2> The metal-polishing composition of <1>, further comprising (e) a nitrogen-containing heterocyclic compound selected from 1,2,3,4-tetrazole and the derivatives thereof

<3> The metal-polishing composition of <1> or <2>, wherein the compound represented by Formula A is at least one compound selected from the group consisting of N-methylglycine, N-ethylglycine, N-methylasparagine, N-methylaspartic acid, N-methylglutamine, N-methylglutamic acid, and N-methylthreonine.

<4> The metal-polishing composition of any one of <1> to <3>, wherein the compound represented by Formula B is at least one compounds selected from the group consisting of 1,2,3-triazole, 1,2,3-triazole-4-carboxylic acid, and 5-methyl-1,2,3-triazole-4-carboxylic acid.

<5> The metal-polishing composition of any one of <1> to <4>, wherein the nitrogen-containing heterocyclic compound selected from 1,2,3,4-tetrazole and the derivatives thereof is a compound having one or more anionic substituents.

<6> The metal-polishing composition of any one of <1> to <4>, wherein the nitrogen-containing heterocyclic compound selected from 1,2,3,4-tetrazole and the derivatives thereof is 5-aminotetrazole.

<7> The metal-polishing composition of any one of <1> to <6>, wherein the content of the abrasive grain is less than 1.0 wt %.

<8> The metal-polishing composition of any one of <1> to <7>, wherein a material to be polished comprises copper.

<9> A chemical mechanical polishing method of polishing a material to be polished of a semiconductor device with a polishing pad on a polishing surface plate, by contacting and relatively moving the polishing pad and the material to be polished while supplying a metal-polishing composition to the polishing pad,

the metal-polishing composition comprising (a) a compound represented by the following Formula A, (b) a compound represented by the following Formula B, (c) an abrasive grain, and (d) an oxidizing agent:

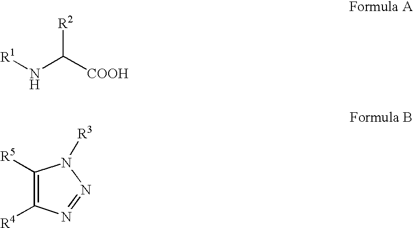

in Formula A, R¹ represents an alkyl group having 1 to 3 carbon atoms; and R² represents a hydrogen atom or an alkyl group having 1 to 4 carbon atoms, and in Formula B, R³, R⁴, and R⁵ each independently represent a hydrogen atom, or an alkyl, aryl, alkoxy, amino, aminoalkyl, hydroxy, hydroxyalkyl, carboxy, carboxyalkyl or carbamoyl group.

<10> The chemical mechanical polishing method of <9>, wherein the polishing pressure is 20 kpa or less.

<11> The chemical mechanical polishing method of <9> or <10>, wherein the supply flow rate of the metal-polishing composition to the polishing pad is 190 ML /min or less.

### EXAMPLES

Hereinafter, the present invention will be described with reference to Examples. It should be understood that the invention is not limited by these Examples.

### Example 1

Polishing Composition

(a) Compound represented by Formula A [a-1] (amount shown in Table 2)

(b) Compound represented by Formula B [b-1] 30 ppm

(c) Abrasive grain [PL-3, manufactured by Fuso Chemical Co., Ltd.] (primary particle diameter: 35 nm,

cocoon-shaped colloidal silica particles) (0.5 wt %, or amount shown in Table 1)

(d) Oxidizing agent (30% hydrogen peroxide) 20 ml/L

pH (pH 7, adjusted by addition of ammonia water)

### Examples 2 to 15

The polishing compositions of Examples 2 to 13 were prepared in a similar manner to Example 1, except that (a) the components to (b) used in Example 1 were replaced with the following components shown in Table 1 and the compound shown in Table 4 was added as (e) the nitrogen-containing heterocyclic compound in the amount shown in Table 4. In addition, the polishing composition of Example 14 was prepared, as (e) the component was replaced with 10 ppm of an anionic surfactant dodecylbenzenesulfonic acid (indicated by “DBS” in Table), and the polishing composition of Example 15, as 1 ppm of a water-soluble polymer sodium polyacrylate (indicated by “PAA” in Table) was added as (e) the component.

### Comparative Example 1

The polishing composition of Comparative Example 1 was prepared in a similar manner to Example 2, except that the compound (B) represented by Formula B was not added as in Example 2.

### Comparative Examples 2 to 4

The polishing compositions of Comparative Examples 2 to 4 were prepared in a similar manner to Example 2, except that (a) the compound represented by Formula A (a-1) used in Example 2 was replaced with a comparative amino acid compound (a-5) to (a-7).

Each of the polishing compositions (polishing solutions) prepared in Examples 1 to 15 and Comparative Examples 1 to 4 was left at room temperature for six months, and the polishing performance (polishing rate, dishing, corrosion) thereof was evaluated, as it was used in polishing by the polishing method shown below. Evaluation results are summarized in Table 1.

### <Evaluation of Polishing Rate>

The film formed on each wafer was polished in a polishing machine “FREX-300” manufactured by Ebara Corporation under the following condition, while the slurry was supplied, and the polishing rate then was calculated.
Substrate: 12-inch silicon wafer with copper film
Table rotational frequency: 104 rpm
Head rotational frequency: 105 rpm
(Processing linear velocity: 1.0 m/s)
Polishing pressure: 105 hPa
Polishing pad: IC-1400 (K-grV)+(A21), manufactured by Rohm and Haas
Slurry supply rate: 190 ml/minute
Measurement of polishing rate: film thickness calculated from the electric resistances before and after polishing, specifically according to the following Formula:

Polishing rate (nm Å/minute)=
(Copper film thickness before polishing—Copper film thickness after polishing)/Polishing period

<Evaluation of Dishing>

The film formed on a patterned wafer was polished by using a polishing machine “FREX-300” manufactured by Ebara Corporation under the following condition while the slurry is supplied, and the level difference was measured.
Substrate: 12-inch wafer prepared by forming wiring grooves and connecting holes of 0.09 to 100 μm in width and 600 nm in depth by patterning of a silicon oxide film in photolithographic and reactive ion-etching processes and forming a Ta film of 20 nm in thickness and a copper film of 50 nm in thickness by sputtering, and thus, forming a copper film having a total thickness of 1,000 nm by plating.
Table rotational frequency: 50 rpm
Head rotational frequency: 50 rpm
Polishing pressure: 168 hPa
Polishing pad: IC-1400 manufactured by Rodel Nitta company
Slurry feed rate: 200 ml/minute
Measurement of level difference: The level difference was determined at a L/S of 100 μm/100 μm by using a needle-type level difference meter.

<Evaluation of Corrosion and Particle>

A wiring having a width of 100 μm on the polishing face was observed under an electron microscope S-4800 manufactured by Hitachi High-Technologies Corp.
Corrosion on the copper wiring surface was observed, and the polished face without corrosion was indicated by “No”. Then, the number of particles remaining on the surface was observed, and the corrosion was evaluated according to the following criteria.
A: Almost no particles (less than 5 particles/100 μm×100 μm)
B: Some particles present (5 or more and less than 50 particles/100 μm×100 μm)
C: Many particles present (more than 50 particles/100 μm×100 μm)
The results are summarized in the following Table 1.

TABLE 1

| | | | (c) Content | | | | | |
|---|---|---|---|---|---|---|---|---|
| | (a) Component or | | of abrasive | | | | | |
| | comparative | | grain | | Polishing | | | |
| | compound | (b) Component | (wt %) | (e) Component | rate nm/min | Dishing nm | Corrosion | Particle |
| Example 1 | a-1 | b-1 | 0.5 | No | 443 | 46 | No | B |
| Example 2 | a-1 | b-1 | 0.5 | e-1 | 420 | 31 | No | B |
| Example 3 | a-2 | b-1 | 0.5 | e-1 | 362 | 43 | No | B |
| Example 4 | a-3 | b-1 | 0.5 | e-1 | 597 | 54 | No | B |
| Example 5 | a-4 | b-1 | 0.5 | e-1 | 608 | 58 | No | B |
| Example 6 | a-1 | b-2 | 0.5 | e-1 | 456 | 45 | No | A |
| Example 7 | a-1 | b-3 | 0.5 | e-1 | 448 | 37 | No | A |
| Example 8 | a-1 | b-1 | 1.0 | e-1 | 452 | 45 | No | B |
| Example 9 | a-1 | b-1 | 3.0 | e-1 | 458 | 49 | No | B |
| Example 10 | a-1 | b-1 | 0.5 | e-2 | 460 | 35 | No | B |
| Example 11 | a-1 | b-1 | 0.5 | e-3 | 456 | 25 | No | B |
| Example 12 | a-1 | b-1 | 0.5 | e-4 | 442 | 46 | No | A |
| Example 13 | a-1 | b-1 | 0.5 | e-1 | 426 | 38 | No | A |
| | | | | e-4 | | | | |
| Example 14 | a-1 | b-1 | 0.5 | DBS | 405 | 30 | No | B |
| | | | | 10 ppm | | | | |
| Example 15 | a-1 | b-1 | 0.5 | PAA | 389 | 35 | No | B |
| | | | | 1 ppm | | | | |
| Comparative | a-1 | No | 0.5 | e-1 | 450 | 95 | No | C |
| Example 1 | | | | | | | | |
| Comparative | a-5* | b-1 | 0.5 | e-1 | 286 | — | No | C |
| Example 2 | | | | | | | | |
| Comparative | a-6* | b-1 | 0.5 | e-1 | 630 | 180 | Yes | C |
| Example 3 | | | | | | | | |
| Comparative | a-7* | b-1 | 0.5 | e-1 | 613 | 160 | Yes | C |
| Example 4 | | | | | | | | |

Details of (a) the compounds represented by Formula A shown in Table 1 and comparative amino acid compounds (indicated by * in Table) are summarized in Table 2, details of (b) the compound represented by Formula B in the following Table 3, and details of (e) the nitrogen-containing heterocyclic compounds selected from 1,2,3,4-tetrazole and the derivatives thereof in Table 4 respectively.

TABLE 2

| | Compound name | | Content (wt %) |
|---|---|---|---|
| a-1 | N-methylglycine | (a) Component | 2 |
| a-2 | N-ethylglycine | (a) Component | 2 |
| a-3 | N-Methylthreonine | (a) Component | 2 |
| a-4 | N-Methylasparagine | (a) Component | 2 |
| a-5 | N-t-Butylglycine | Comparative amino | 2 |
| | | acid | |
| a-6 | Glycine | Comparative amino | 1 |
| | | acid | |
| a-7 | Asparagine | Comparative amino | 2 |
| | | acid | |

TABLE 3

| | (b) Compound name of component | Addition concentration |
|---|---|---|
| b-1 | 1,2,3-Triazole | 30 ppm |
| b-2 | 1,2,3-triazole-4-carboxylic acid | 30 ppm |
| b-3 | 5-Methyl-1,2,3-triazole-4-carboxylic acid | 30 ppm |

TABLE 4

| | (e) Compound name of component | Addition concentration |
|---|---|---|
| e-1 | 1,2,3,4-Tetrazole | 80 ppm |
| e-2 | 5-Methyl-1,2,3,4-tetrazole | 80 ppm |
| e-3 | 5-Amino-1,2,3,4-tetrazole | 80 ppm |
| e-4 | 1,2,3,4-Tetrazole-5-acetic acid | 10 ppm |

As apparent from Table 1, in all Examples 1 to 15 wherein a polishing composition containing a particular amino acid compound as component (a) and a particular heterocyclic compound as heteroaromatic ring compound (b) was used, it was possible to inhibit both dishing, wiring defects and particle deposition on the substrate surface while retaining the favorable polishing rate and thus to obtain advantageous effects.

An object of the invention is to provide a metal-polishing composition effectively inhibiting both dishing and copper wiring defects by corrosion.

Another object of the invention is to provide a chemical mechanical polishing method by using the metal-polishing composition according to the invention that inhibits dishing, and wiring defects on the semiconductor device surface after polishing.

The invention provides a metal-polishing composition resistant to dishing and generation of copper wiring defects, by reducing the copper corrosion rate while retaining the polishing rate.

It also provides a chemical mechanical polishing method by using the metal-polishing composition that inhibit dishing and wiring defects on the semiconductor device surface after polishing.

All publications, patent applications, and technical standards mentioned in this specification are herein incorporated by reference to the same extent as if each individual publication, patent application, or technical standard was specifically and individually indicated to be incorporated by reference.

What is claimed is:

1. A metal-polishing composition for use in chemical mechanical polishing of semiconductor devices, comprising:
(a) a compound represented by the following Formula A, (b) a compound represented by the following Formula B, (c) an abrasive grain, and (d) an oxidizing agent: 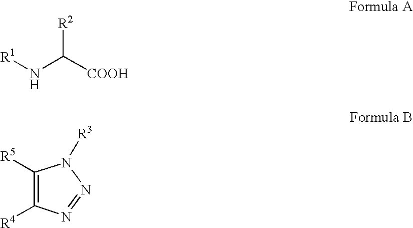
in Formula A, R¹ represents an alkyl group having 1 to 3 carbon atoms; and R² represents a hydrogen atom or an alkyl group having 1 to 4 carbon atoms, and in Formula B, R³, R⁴, and R⁵ each independently represent a hydrogen atom, or an alkyl, aryl, alkoxy, amino, aminoalkyl, hydroxy, hydroxyalkyl, carboxy, carboxyalkyl or carbamoyl group.

2. The metal-polishing composition of claim 1, further comprising (e) a nitrogen-containing heterocyclic compound selected from 1,2,3,4-tetrazole and the derivatives thereof.

3. The metal-polishing composition of claim 1, wherein the compound represented by Formula A is at least one compound selected from the group consisting of N-methylglycine, N-ethylglycine, N-methylasparagine, N-methylaspartic acid, N-methylglutamine, N-methylglutamic acid, and N-methylthreonine.

4. The metal-polishing composition of claim 1, wherein the compound represented by Formula B is at least one compounds selected from the group consisting of 1,2,3-triazole, 1,2,3-triazole-4-carboxylic acid, and 5-methyl-1,2,3-triazole-4-carboxylic acid.

5. The metal-polishing composition of claim 2, wherein the nitrogen-containing heterocyclic compound selected from 1,2,3,4-tetrazole and the derivatives thereof is a compound having one or more anionic substituents.

6. The metal-polishing composition of claim 2, wherein the nitrogen-containing heterocyclic compound selected from 1,2,3,4-tetrazole and the derivatives thereof is 5-aminotetrazole.

7. The metal-polishing composition of claim 1, wherein the content of the abrasive grain is less than 1.0 wt %.

8. The metal-polishing composition of claim 1, wherein a material to be polished comprises copper.

9. A chemical mechanical polishing method of polishing a material to be polished of a semiconductor device with a polishing pad on a polishing surface plate, by contacting and relatively moving the polishing pad and the material to be polished while supplying a metal-polishing composition to the polishing pad,
the metal-polishing composition comprising (a) a compound represented by the following Formula A, (b) a compound represented by the following Formula B, (c) an abrasive grain, and (d) an oxidizing agent: 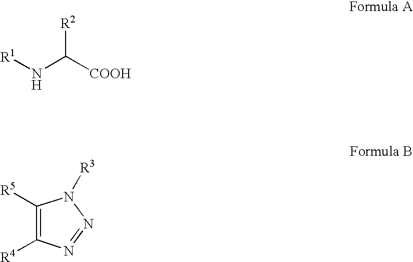
in Formula A, R¹ represents an alkyl group having 1 to 3 carbon atoms; and R² represents a hydrogen atom or an alkyl group having 1 to 4 carbon atoms, and in Formula B, R³, R⁴, and R⁵ each independently represent a hydrogen atom, or an alkyl, aryl, alkoxy, amino, aminoalkyl, hydroxy, hydroxyalkyl, carboxy, carboxyalkyl or carbamoyl group.

10. The chemical mechanical polishing method of claim 9, wherein the polishing pressure is 20 kpa or less.

11. The chemical mechanical polishing method of claim 9, wherein the supply flow rate of the metal-polishing composition to the polishing pad is 190 mL /min or less.
